(19) United States
(12) Patent Application Publication
(10) Pub. No.: US 2024/0413146 A1
(43) Pub. Date: Dec. 12, 2024

(54) METHOD OF MANUFACTURING SEMICONDUCTOR DEVICE AND SEMICONDUCTOR DEVICE

(71) Applicant: Tokyo Electron Limited, Tokyo (JP)

(72) Inventors: Tetsu OHTOU, Tokyo (JP); Kiyotaka IMAI, Tokyo (JP); Tomonari YAMAMOTO, Tokyo (JP); Takuo KAWAUCHI, Tokyo (JP); Yoshihiro TSUTSUMI, Tokyo (JP)

(21) Appl. No.: 18/699,419

(22) PCT Filed: Oct. 13, 2022
(86) PCT No.: PCT/JP2022/038264

§ 371 Date: Apr. 8, 2024

(30) Foreign Application Priority Data
Oct. 21, 2021 (JP) 2021-172576

(51) Int. Cl. H01L 27/02; H01L 21/8234; H01L 23/528; H01L 27/088

(52) U.S. Cl. CPC H01L 27/0207; H01L 21/823475; H01L 23/5283; H01L 27/088

(57) ABSTRACT

A method of manufacturing a semiconductor device includes forming a laminated film by laminating an N-type channel and a P-type channel on a substrate; performing patterning on the laminated film; forming a source and a drain on a front surface side; bonding a new substrate on the front surface side and removing the substrate on a back surface side; forming a source and a drain on the back surface side; and a step of forming a gate on the back surface side.

### TECHNICAL FIELD

The present disclosure relates to a method of manufacturing a semiconductor device and the semiconductor device.

### BACKGROUND

A semiconductor device including a P-type field effect transistor (FET) and an N-type field effect transistor is known. Patent Document 1 and Patent Document 2 disclose methods of forming a semiconductor device.

### RELATED ART DOCUMENT

### Patent Document

[Patent Document 1] U.S. Patent Application Publication No. 2021/0175209
[Patent Document 2] U.S. Patent Application Publication No. 2021/0175358

### SUMMARY OF THE INVENTION

### Problem to be Solved by the Invention

According to one aspect, the present disclosure provides a method of manufacturing a semiconductor device that increases the number of transistors per area of a substrate and the semiconductor device.

### Means for Solving Problem

According to one aspect of the present invention, a method of manufacturing a semiconductor device, including a step of forming a laminated film by laminating an N-type channel and a P-type channel on a substrate; a step of performing patterning on the laminated film; a step of forming a source and a drain on a front surface side of the substrate; a step of bonding a new substrate on the front surface side and removing the substrate on a back surface side of the substrate; a step of forming a source and a drain on the back surface side; and a step of forming a gate on the back surface side is provided in order to solve the above-described problem.

### Effect of the Invention

According to one aspect, a method of manufacturing a semiconductor device that increases the number of transistors per area of a substrate and the semiconductor device can be provided.

### BRIEF DESCRIPTION OF THE DRAWINGS

FIG. 1 is a perspective view illustrating an example of a structure of a semiconductor device.

FIG. 2 is an example of a flowchart for explaining a method of manufacturing a semiconductor device according to a first embodiment.

FIG. 3 is an example of a cross-sectional view illustrating a structure of the semiconductor device in step S101.

FIG. 4 is an example of a cross-sectional view illustrating a structure of the semiconductor device in step S102.

FIG. 5 is an example of a cross-sectional view illustrating a structure of the semiconductor device in step S103.

FIG. 6 is an example of a cross-sectional view illustrating a structure of the semiconductor device in step S104.

FIG. 7A is an example of a top view of the semiconductor device in step S105.

FIG. 7B is an example of a cross-sectional view illustrating a structure of the semiconductor device in step S105.

FIG. 7C is an example of the cross-sectional view illustrating the structure of the semiconductor device in step S105.

FIG. 7D is an example of the cross-sectional view illustrating the structure of the semiconductor device in step S105.

FIG. 7E is an example of the cross-sectional view illustrating the structure of the semiconductor device in step S105.

FIG. 8A is an example of a top view of the semiconductor device in step S106.

FIG. 8B is an example of a cross-sectional view illustrating a structure of the semiconductor device in step S106.

FIG. 8C is an example of the cross-sectional view illustrating the structure of the semiconductor device in step S106.

FIG. 8D is an example of the cross-sectional view illustrating the structure of the semiconductor device in step S106.

FIG. 8E is an example of the cross-sectional view illustrating the structure of the semiconductor device in step S106.

FIG. 9A is an example of a cross-sectional view illustrating a structure of the semiconductor device in step S107.

FIG. 9B is an example of the cross-sectional view illustrating the structure of the semiconductor device in step S107.

FIG. 9C is an example of the cross-sectional view illustrating the structure of the semiconductor device in step S107.

FIG. 9D is an example of the cross-sectional view illustrating the structure of the semiconductor device in step S107.

FIG. 10 is an example of a cross-sectional view illustrating a structure of the semiconductor device in step S108.

FIG. 11 is an example of a cross-sectional view illustrating a structure of the semiconductor device in step S109.

FIG. 12 is an example of a cross-sectional view illustrating a structure of the semiconductor device in step S110.

FIG. 13 is an example of a cross-sectional view illustrating a structure of the semiconductor device in step S111.

FIG. 14 is an example of a cross-sectional view illustrating a structure of the semiconductor device in step S112.

FIG. 15 is an example of a cross-sectional view illustrating a structure of the semiconductor device in step S113.

FIG. 16 is an example of a cross-sectional view illustrating a structure of the semiconductor device in step S114.

FIG. 17 is an example of a cross-sectional view illustrating a structure of the semiconductor device in step S115 and step S116.

FIG. 18 is an example of a cross-sectional view illustrating a structure of the semiconductor device in step S117.

FIG. 19 is an example of a cross-sectional view illustrating a structure of the semiconductor device in step S118.

FIG. 20 is an example of a cross-sectional view illustrating a structure of the semiconductor device in step S119.

FIG. 21A is an example of a cross-sectional view of a semiconductor device for explaining a method of manufacturing a semiconductor device according to a first reference example.

FIG. 21B is an example of the cross-sectional view of the semiconductor device for explaining the method of manufacturing the semiconductor device according to the first reference example.

FIG. 21C is an example of the cross-sectional view of the semiconductor device for explaining the method of manufacturing the semiconductor device according to the first reference example.

FIG. 21D is an example of the cross-sectional view of the semiconductor device for explaining the method of manufacturing the semiconductor device according to the first reference example.

FIG. 21E is an example of the cross-sectional view of the semiconductor device for explaining the method of manufacturing the semiconductor device according to the first reference example.

FIG. 21F is an example of the cross-sectional view of the semiconductor device for explaining the method of manufacturing the semiconductor device according to the first reference example.

FIG. 21G is an example of the cross-sectional view of the semiconductor device for explaining the method of manufacturing the semiconductor device according to the first reference example.

FIG. 21H is an example of the cross-sectional view of the semiconductor device for explaining the method of manufacturing the semiconductor device according to the first reference example.

FIG. 22A is an example of a cross-sectional view of a semiconductor device for explaining a method of manufacturing a semiconductor device according to a second reference example.

FIG. 22B is an example of the cross-sectional view of the semiconductor device for explaining the method of manufacturing the semiconductor device according to the second reference example.

FIG. 22C is an example of the cross-sectional view of the semiconductor device for explaining the method of manufacturing the semiconductor device according to the second reference example.

FIG. 22D is an example of the cross-sectional view of the semiconductor device for explaining the method of manufacturing the semiconductor device according to the second reference example.

FIG. 22E is an example of the cross-sectional view of the semiconductor device for explaining the method of manufacturing the semiconductor device according to the second reference example.

FIG. 22F is an example of the cross-sectional view of the semiconductor device for explaining the method of manufacturing the semiconductor device according to the second reference example.

FIG. 22G is an example of the cross-sectional view of the semiconductor device for explaining the method of manufacturing the semiconductor device according to the second reference example.

FIG. 23 is an example of a flowchart for explaining a method of manufacturing a semiconductor device according to a second embodiment.

FIG. 24A is an example of a cross-sectional view of a semiconductor device for explaining the method of manufacturing the semiconductor device according to the second embodiment.

FIG. 24B is an example of the cross-sectional view of a semiconductor device for explaining the method of manufacturing the semiconductor device according to the second embodiment.

FIG. 24C is an example of the cross-sectional view of a semiconductor device for explaining the method of manufacturing the semiconductor device according to the second embodiment.

FIG. 24D is an example of the cross-sectional view of a semiconductor device for explaining the method of manufacturing the semiconductor device according to the second embodiment.

FIG. 24E is an example of the cross-sectional view of a semiconductor device for explaining the method of manufacturing the semiconductor device according to the second embodiment.

FIG. 24F is an example of the cross-sectional view of a semiconductor device for explaining the method of manufacturing the semiconductor device according to the second embodiment.

FIG. 24G is an example of the cross-sectional view of a semiconductor device for explaining the method of manufacturing the semiconductor device according to the second embodiment.

FIG. 24H is an example of the cross-sectional view of a semiconductor device for explaining the method of manufacturing the semiconductor device according to the second embodiment.

FIG. 24I is an example of the cross-sectional view of a semiconductor device for explaining the method of manufacturing the semiconductor device according to the second embodiment.

FIG. 25 is an example of a block diagram for explaining the method of manufacturing the semiconductor device according to the first embodiment.

FIG. 26 is an example of a block diagram for explaining the method of manufacturing the semiconductor device according to the second embodiment.

### DESCRIPTION OF EMBODIMENTS

In the following, embodiments of the present disclosure will be described with reference to the drawings. In the drawings, the same components are denoted by the same reference symbols, and a duplicated description thereof may be omitted.

### [Semiconductor Device]

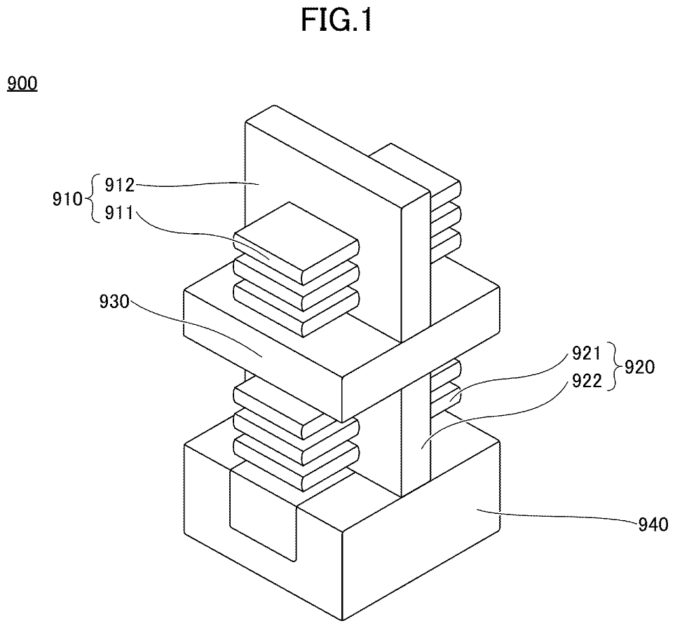

First, an example of a semiconductor device 900 is described using FIG. 1. FIG. 1 is a perspective view illustrating an example of a structure of the semiconductor device 900.

The semiconductor device 900 is a field-effect transistor (FET) and has a complementary FET (CFET) structure in which a P-type FET 910 and an N-type FET 920 are stacked vertically. The P-type FET 910 includes a P-type channel 911 and a gate 912. The gate 912 is formed to cover a periphery of the P-type channel 911. Similarly, the N-type FET 920 includes an N-type channel 921 and a gate 922. The gate 922 is formed to cover a periphery of the N-type channel 921.

Additionally, the semiconductor device 900 is formed by stacking an insulating film 940 formed on a wafer (not illustrated), the N-type FET 920 formed on the insulating film 940, an insulating film 930 formed on the N-type FET 920, and the P-type FET 910 formed on the insulating film 930.

The semiconductor device 900 has a complementary FET (CFET) structure in which the P-type FET 910 and the N-type FET 920 are stacked vertically, so that the number of transistors per area of the wafer (substrate) can be increased.

### [Method of Manufacturing Semiconductor Device According to First Embodiment]

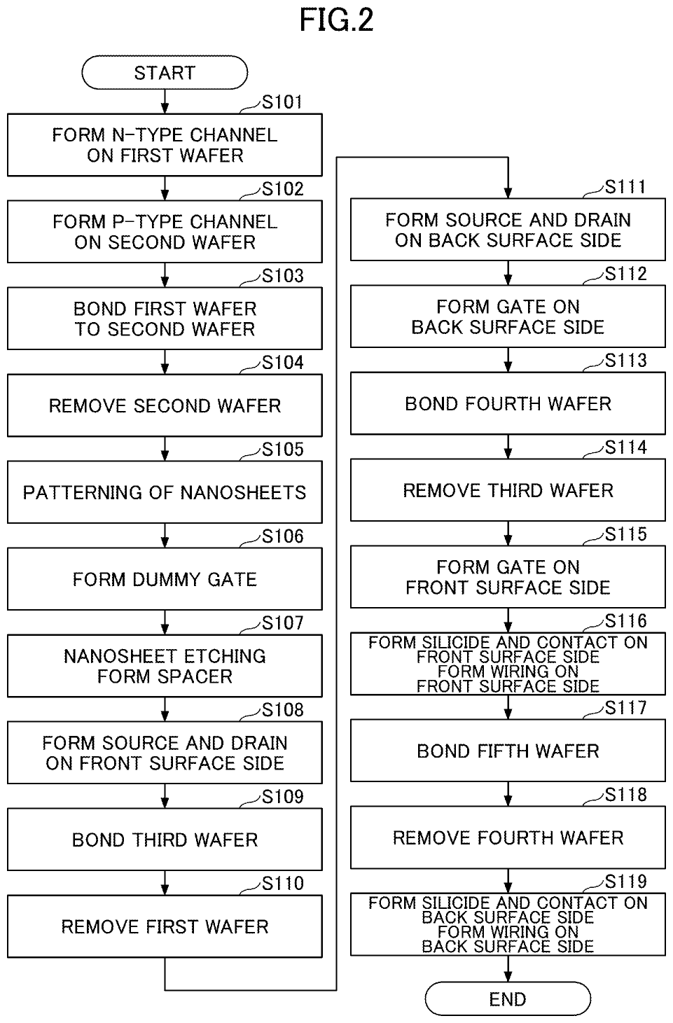

Next, a method of manufacturing a semiconductor device will be described using FIG. 2 to FIG. 20. FIG. 2 is an example of a flowchart for explaining a method of manufacturing a semiconductor device according to a first embodiment.

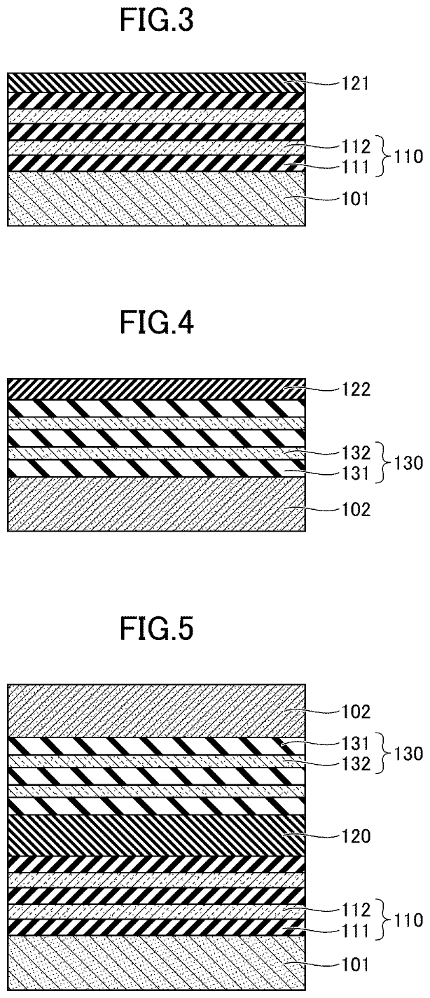

In step S101, an N-type channel is formed on a first wafer 101. FIG. 3 is an example of a cross-sectional view illustrating a structure of the semiconductor device in step S101.

As illustrated in FIG. 3, a laminated body 110 in which dummy films 111 and channel material films (hereinafter, also referred to as the N-type channels) 112 to be the N-type channels are alternately laminated is formed on the first wafer 101, which is a silicon substrate. Additionally, an insulating film 121 is formed on the laminated body 110.

Here, as a combination of materials of the channel material film 112 and the dummy film 111, for example, the following combinations of materials can be used. For example, when silicon is used as the channel material film 112, silicon germanium can be used as the dummy film 111. When silicon germanium is used as the channel material film 112, silicon can be used as the dummy film 111. When silicon germanium is used as the channel material film 112, germanium can be used as the dummy film 111. When germanium is used as the channel material film 112, silicon germanium can be used as the dummy film 111. When germanium is used as the channel material film 112, impurity-doped germanium can be used as the dummy film 111. When any one of a molybdenum disulfide film (MoS₂), a tungsten disulfide film (WS₂), a molybdenum diselenide film (MoSe₂), or a tungsten diselenide film (WSe₂) is used as the channel material film 112, any one of graphene, hexagonal boron nitride (hBN), or another insulating film can be used as the dummy film 111. With this, in step S115 described later, the dummy film 111 can be selectively removed from the laminated body 110.

Additionally, as the insulating film 121, for example, a silicon dioxide film (SiO₂), a silicon nitride film (SiN), a SiCN film, a SiOCN film, or the like can be used. With this, in step S103 described later, the insulating film 121 and the insulating film 122 can be suitably bonded to each other.

In step S102, a P-type channel is formed on a second wafer 102 different from the first wafer 101. FIG. 4 is an example of a cross-sectional view illustrating a structure of the semiconductor device in step S102.

As illustrated in FIG. 4, a laminated body 130 in which dummy films 131 and channel material films (hereinafter, also referred to as P-type channels) 132 to be P-type channels are alternately laminated is formed on the second wafer 102, which is a silicon substrate. Additionally, an insulating film 122 is formed on the laminated body 130.

Here, for a combination of the materials of the channel material film 132 and the dummy film 131, the combination of materials of the channel material film 112 and the dummy film 111 can be used. With this, in step S112 described later, the dummy film 131 can be selectively removed from the laminated body 130.

Additionally, as the insulating film 122, a material substantially the same as that of the insulating film 121 can be used. With this, in step S103 described later, the insulating film 121 and the insulating film 122 can be suitably bonded to each other.

In step S103, the first wafer 101 including the N-type channel 112 and the second wafer 102 including the P-type channel 132 are bonded to each other. FIG. 5 is an example of a cross-sectional view illustrating a structure of the semiconductor device in step S103.

As illustrated in FIG. 5, the insulating film 121 and the insulating film 122 are bonded to form an insulating film 120. Additionally, the P-type channel material film (P-type channel) 132 is formed over the N-type channel material film (N-type channel) 112.

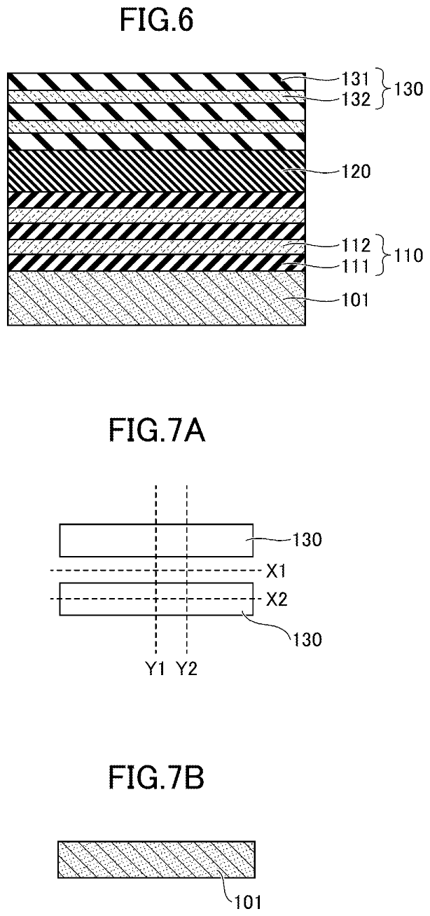

In step S104, the second wafer 102 is removed. FIG. 6 is an example of a cross-sectional view illustrating a structure of the semiconductor device in step S104.

As illustrated in FIG. 6, the second wafer 102 is removed. Here, a method of removing the second wafer 102 includes removing by grinding the second wafer 102, removing by lifting off the second wafer 102, removing by cleaving the second wafer 102, or removing by debonding the second wafer 102. With this, a laminated film in which the N-type channel 112, the insulating film 120, and the P-type channel 132 are laminated is formed on the first wafer 101.

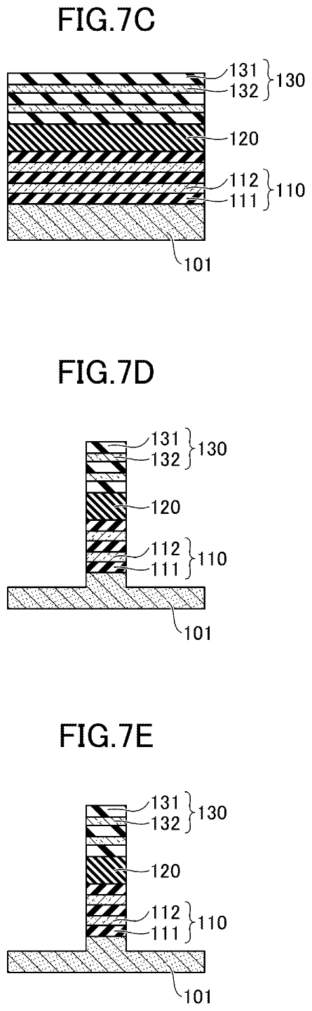

In step S105, the laminated film formed on the first wafer 101 is etched to perform patterning of nanosheets. FIG. 7A is an example of a top view of the semiconductor device in step S105. FIG. 7B to FIG. 7E are examples of a cross-sectional view illustrating a structure of the semiconductor device in step S105. FIG. 7B is the example of the cross-sectional view of the semiconductor device taken along a dashed line X1 illustrated in FIG. 7A. FIG. 7C is the example of the cross-sectional view of the semiconductor device taken along a dashed line X2 illustrated in FIG. 7A. FIG. 7D is the example of the cross-sectional view of the semiconductor device taken along a dashed line Y1 illustrated in FIG. 7A. FIG. 7E is an example of a cross-sectional view of the semiconductor device taken along a dashed line Y2 illustrated in FIG. 7A. Here, in FIG. 7B to FIG. 7E, cross sections of one nanosheet are illustrated.

As illustrated in FIG. 7, a laminated film formed by laminating the laminated body 110 (the dummy film 111 and the N-type channel 112), the insulating film 120, and the laminated body 130 (the dummy film 131 and the P-type channel 132) is etched to form multiple rectangular nanosheets.

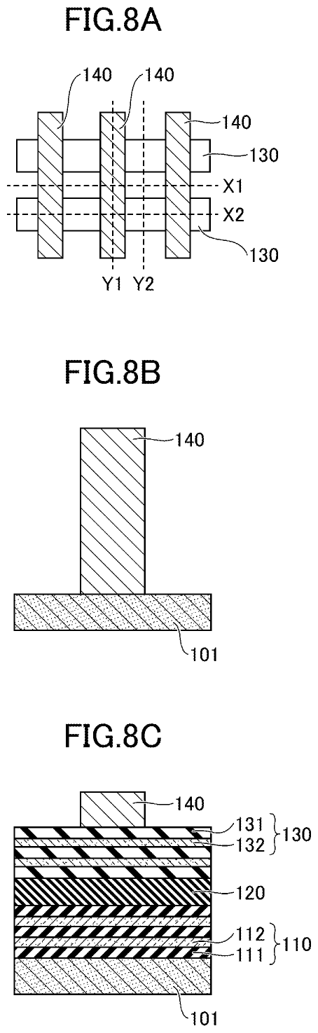

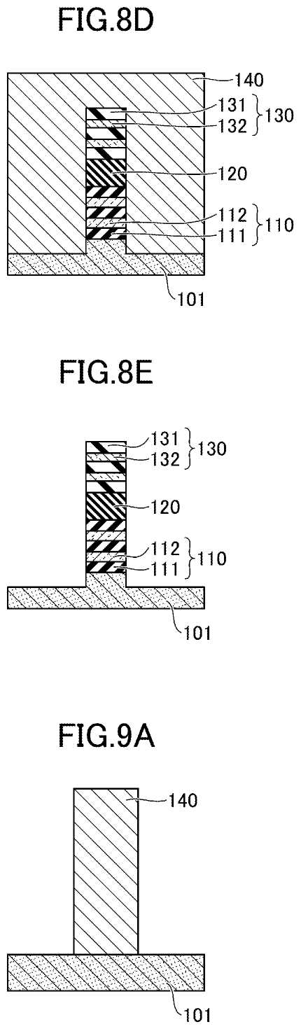

In step S106, the dummy gate material film is formed to form a dummy gate 140. FIG. 8A is an example of a top view of the semiconductor device in step S106. FIG. 8B to FIG. 8E are examples of a cross-sectional view illustrating a structure of the semiconductor device in step S106. FIG. 8B is the example of the cross-sectional view of the semiconductor device taken along a dashed line X1 illustrated in FIG. 8A. FIG. 8C is the example of the cross-sectional view of the semiconductor device taken along a dashed line X2 illustrated in FIG. 8A. FIG. 8D is the example of the cross-sectional view of the semiconductor device taken along a dashed line Y1 illustrated in FIG. 8A. FIG. 8E is the example of the cross-sectional view of the semiconductor device taken along a dashed line Y2 illustrated in FIG. 8A.

First, a dummy gate material film, which is to be the dummy gate 140, is formed on the first wafer 101 (see FIG. 7A to FIG. 7E) on which the nanosheets are formed. As the dummy gate material film, for example, a polysilicon film is formed. Next, as illustrated in FIG. 8A to FIG. 8E, the dummy gate material film is etched to form multiple dummy gates 140 so as to intersect with the multiple rectangular nanosheets.

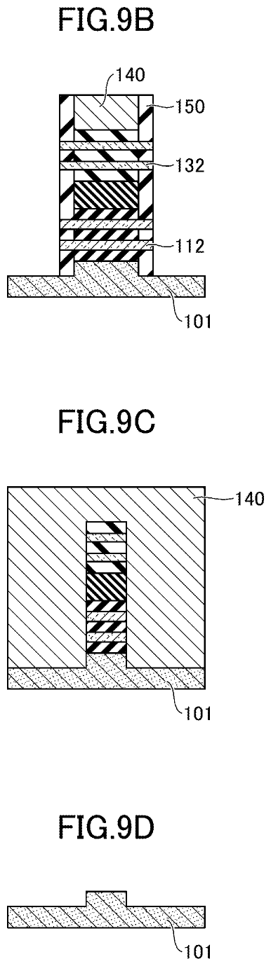

In step S107, the nanosheet exposed from the dummy gate 140 is etched to form a spacer 150. FIG. 9A to FIG. 9D are examples of a cross-sectional view illustrating a structure of the semiconductor device in step S107. Additionally, FIG. 9A is an example of a cross-sectional view of the semiconductor device taken along the dashed line X1 (see FIG. 8A). FIG. 9B is an example of a cross-sectional view of the semiconductor device taken along the dashed line X2 (see FIG. 8A). FIG. 9C is an example of a cross-sectional view of the semiconductor device taken along the dashed line Y1 (see FIG. 8A). FIG. 9D is an example of a cross-sectional view of the semiconductor device taken along the dashed line Y2 (see FIG. 8A).

First, the nanosheet exposed from the dummy gate 140 is etched. That is, when viewed from above, the columnar nanosheet remains at a position where the nanosheet and the dummy gate 140 intersect. Further, side surfaces of the dummy film 111, the insulating film 120, the dummy film 131, and the dummy gate 140 are selectively etched to be recessed from side surfaces of the N-type channel 112 and the P-type channel 132. Next, an insulating material film, which is to be the spacer 150, is formed and the insulating material film is etched to form the spacer 150. Here, as illustrated in FIG. 9B, the N-type channel 112 and the P-type channel 132 are exposed from the spacer 150.

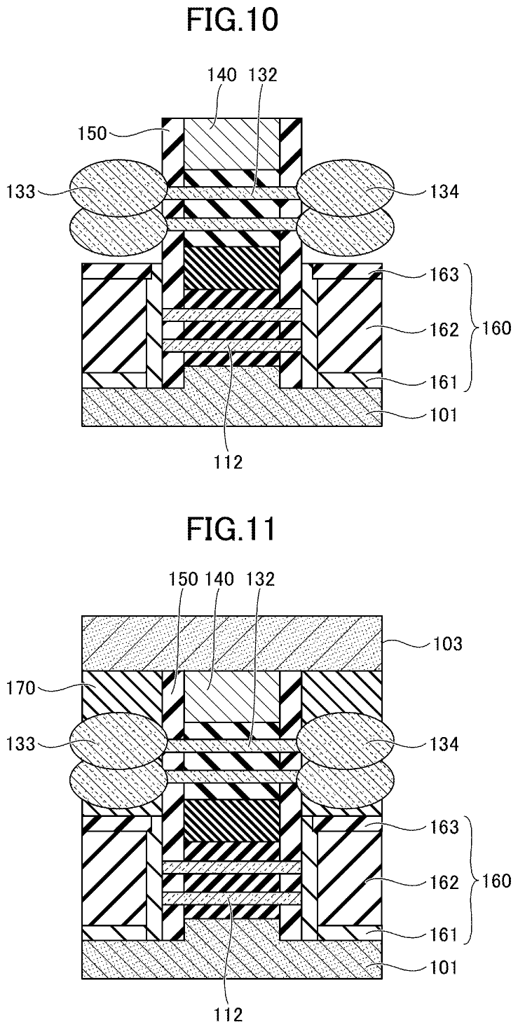

In step S108, a source 133 and a drain 134 on the front surface side (the side of the P-type channel 132) are formed. FIG. 10 is an example of a cross-sectional view illustrating a structure of the semiconductor device in step S108. Here, FIG. 10 to FIG. 20 are examples of a cross-sectional view of the semiconductor device taken along the dashed line X2 (see FIG. 8A).

First, an insulating film 161, an insulating film 162, and an insulating film 163 are formed, so that the N-type channel 112 exposed from the spacer 150 is covered by an insulating film 160. Next, as illustrated in FIG. 10, the source 133 and the drain 134 of the P-type FET are formed by selective epitaxial growth from the side surfaces of the P-type channel 132 exposed from the spacer 150.

Subsequently, an insulating film 170 (see FIG. 11) is formed on the insulating film 160. With this, spaces around the source 133 and the drain 134 are filled with the insulating film 170.

In step S109, a third wafer 103 and the first wafer 101 are bonded to each other. FIG. 11 is an example of a cross-sectional view illustrating a structure of the semiconductor device in step S109.

As illustrated in FIG. 11, the third wafer 103, which is a silicon substrate, is bonded on the front surface side (the side of the P-type channel 132).

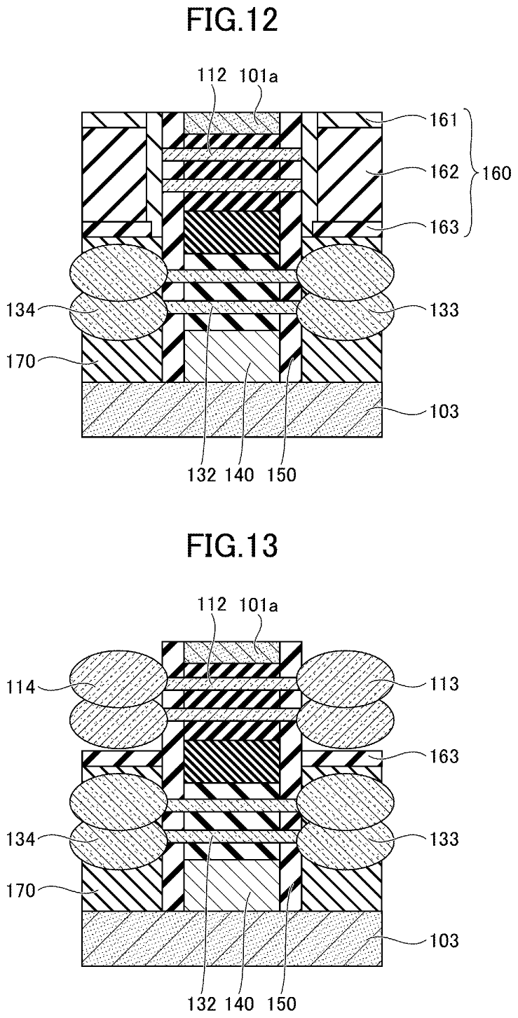

In step S110, the first wafer 101 is removed. FIG. 12 is an example of a cross-sectional view illustrating a structure of the semiconductor device in step S110.

As illustrated in FIG. 12, the first wafer 101 is removed. Here, a method of removing the first wafer 101 includes removing by grinding the first wafer 101, removing by lifting off the first wafer 101, removing by cleaving the first wafer 101, or removing by debonding the first wafer 101. Here, a silicon layer 101a may remain when the first wafer 101 is removed.

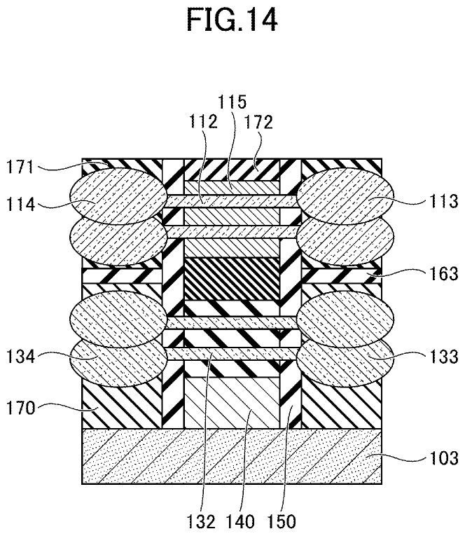

In step S111, a source 113 and a drain 114 on the back surface side (the side of the N-type channel 112) are formed. FIG. 13 is an example of a cross-sectional view illustrating a structure of the semiconductor device in step S111.

First, the insulating film 161 and the insulating film 162 are removed by etching to expose the N-type channel 112 from the spacer 150. Next, as illustrated in FIG. 13, the source 113 and the drain 114 of the N-type FET are formed by selective epitaxial growth from the side surfaces of the N-type channel 112 exposed from the spacer 150.

Subsequently, an insulating film 171 (see FIG. 14) is formed on the insulating film 163. With this, spaces around the source 113 and the drain 114 are filled with the insulating film 171.

In step S112, a gate 115 on the back surface side (the side of the N-type channel 112) is formed. FIG. 14 is an example of a cross-sectional view illustrating a structure of the semiconductor device in step S112.

First, the silicon layer 101a and the dummy film 111 are etched to expose the N-type channel 112. Next, a gate insulating film (not illustrated) is formed around the N-type channel 112. Next, the gate 115 is formed around the N-type channel 112 where the gate insulating film is formed. Next, an insulating film 172 is formed on the gate 115.

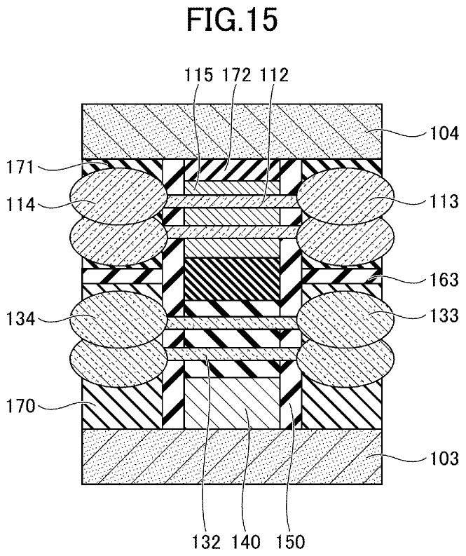

In step S113, a fourth wafer 104 and the third wafer 103 are bonded to each other. FIG. 15 is an example of a cross-sectional view illustrating a structure of the semiconductor device in step S113.

As illustrated in FIG. 15, the fourth wafer 104, which is a silicon substrate, is bonded on the back surface side (the side of the N-type channel 112).

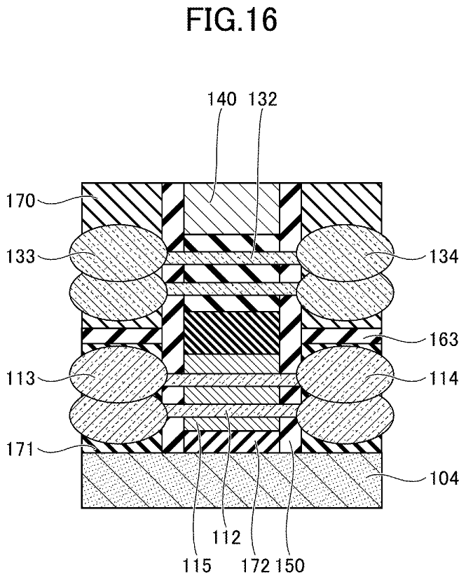

In step S114, the third wafer 103 is removed. FIG. 16 is an example of a cross-sectional view illustrating a structure of the semiconductor device in step S114.

As illustrated in FIG. 16, the third wafer 103 is removed. Here, a method of removing the third wafer 103 includes removing by grinding the third wafer 103, removing by lifting off the third wafer 103, removing by cleaving the third wafer 103, or removing by debonding the third wafer 103.

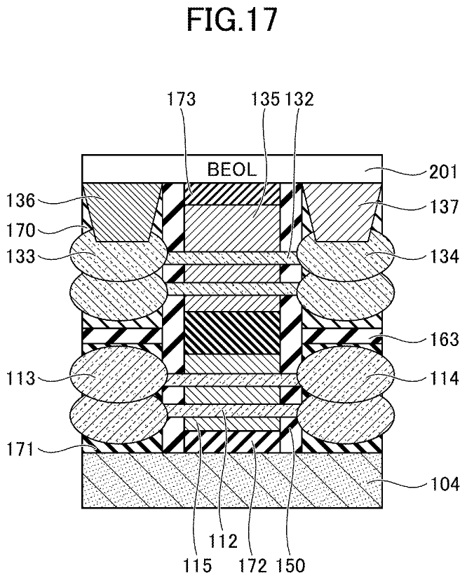

In step S115, a gate 135 on the front surface side (the side of the P-type channel 132) is formed. FIG. 17 is an example of a cross-sectional view illustrating a structure of the semiconductor device in step S115 and step S116.

First, the dummy gate 140 and the dummy film 131 are etched to expose the P-type channel 132. Next, a gate insulating film (not illustrated) is formed around the P-type channel 132. Next, the gate 135 is formed around the P-type channel 132 where the gate insulating film is formed. Next, an insulating film 173 is formed on the gate 135.

In step S116, silicide (not illustrated) and contacts 136 and 137 are formed for the source 133, the drain 134, and the gate 135 on the front surface side (the side of the P-type channel 132). Here, the contact 136 of the source 133, the contact 137 of the drain 134, and a contact (not illustrated) of the gate 135 are formed.

Next, wiring (BEOL: Back End of Line) 201 is formed on the front surface side (the side of the P-type channel 132).

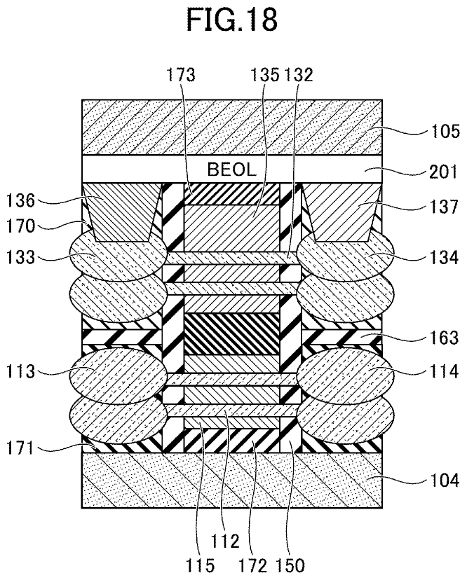

In step S117, a fifth wafer 105 is bonded to the fourth wafer 104. FIG. 18 is an example of a cross-sectional view illustrating a structure of the semiconductor device in step S117.

As illustrated in FIG. 18, the fifth wafer 105, which is a silicon substrate, is bonded on the back surface side (the side of the N-type channel 112).

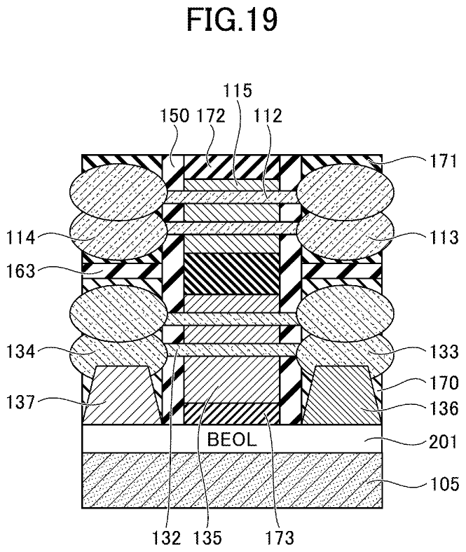

In step S118, the fourth wafer 104 is removed. FIG. 19 is an example of a cross-sectional view illustrating a structure of the semiconductor device in step S118.

As illustrated in FIG. 19, the fourth wafer 104 is removed. Here, a method of removing the fourth wafer 104 includes removing by grinding the fourth wafer 104, removing by lifting off the fourth wafer 104, removing by cleaving the fourth wafer 104, or removing by debonding the fourth wafer 104.

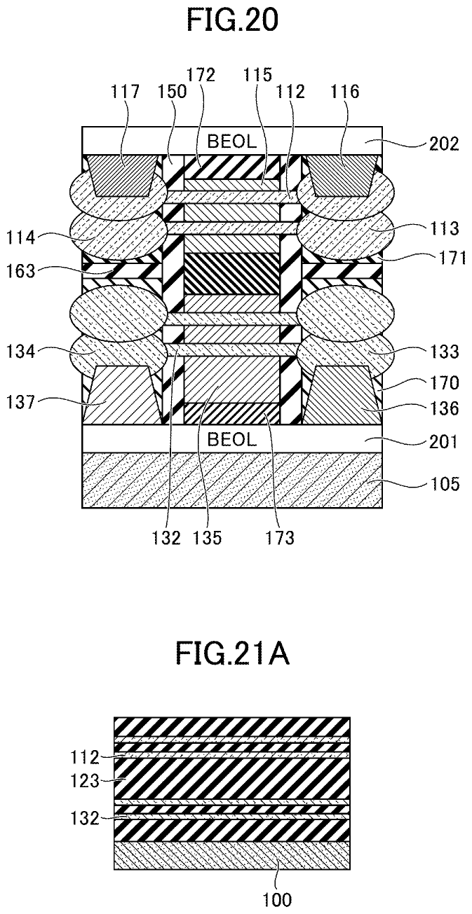

In step S119, a silicide (not illustrated) and contacts 116 and 117 are formed for the source 113, the drain 114, and the gate 115 on the back surface side (the side of the N-type channel 112). FIG. 20 is an example of a cross-sectional view illustrating a structure of the semiconductor device in step S119. Here, the contact 116 of the source 113, the contact 117 of the drain 114, and a contact (not illustrated) of the gate 115 are formed.

Next, wiring (BEOL: Back End of Line) 202 is formed on the back surface side (the side of the N-type channel 112).

As described above, according to the method of manufacturing the semiconductor device of the first embodiment, a semiconductor device having a complementary FET (CFET) structure in which a P-type FET and an N-type FET are vertically stacked can be manufactured.

Here, as illustrated in FIG. 20, the description assumes that the contacts of the P-type FET and the N-type FET are respectively formed on the front surface side and the back surface side of the semiconductor device, and the wirings (BEOL) 201 and 202 are formed on both surfaces of the semiconductor device, but is not limited thereto. A configuration in which wiring (BEOL) is formed on one surface of the semiconductor device may be adopted.

For example, in step S116, the contact 136 of the source 133, the contact 137 of the drain 134, and the contact (not illustrated) of the gate 135 are formed for the source 133, the drain 134, and the gate 135 on the front surface side (the P-type channel 132 side), and further, a contact (not illustrated) of the source 113, a contact (not illustrated) of the drain 114, and the contact (not illustrated) of the gate 135 may be formed for the source 113, the drain 114, and the gate 115 on the back surface side (the side of the N-type channel 112). Then, it may be configured to form wiring (BEOL) connecting the contacts of the P-type FET (the contact 136 of the source 133, the contact 137 of the drain 134, and the contact (not illustrated) of the gate 135) and the contacts of the N-type FET (the contact (not illustrated) of the source 113, the contact (not illustrated) of the drain 114, and the contact (not illustrated) of the gate 135). With this, a semiconductor device having wiring (BEOL) formed on one surface can be manufactured.

### First Reference Example

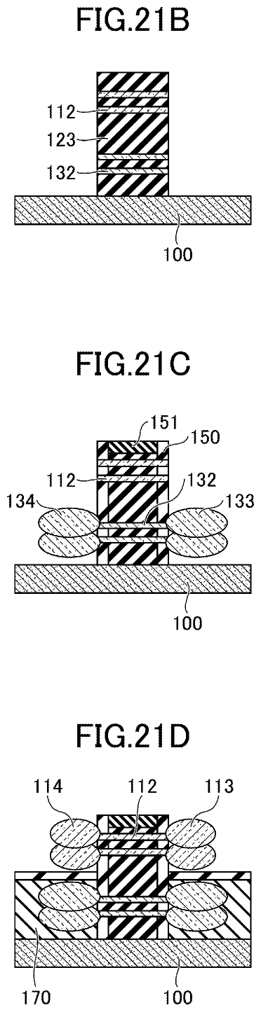

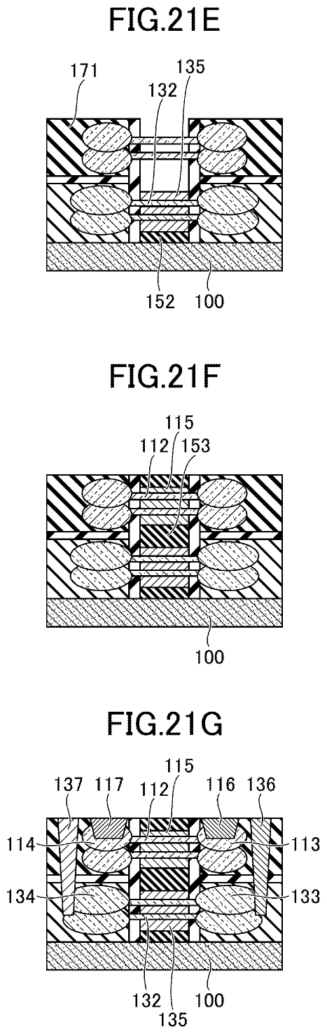

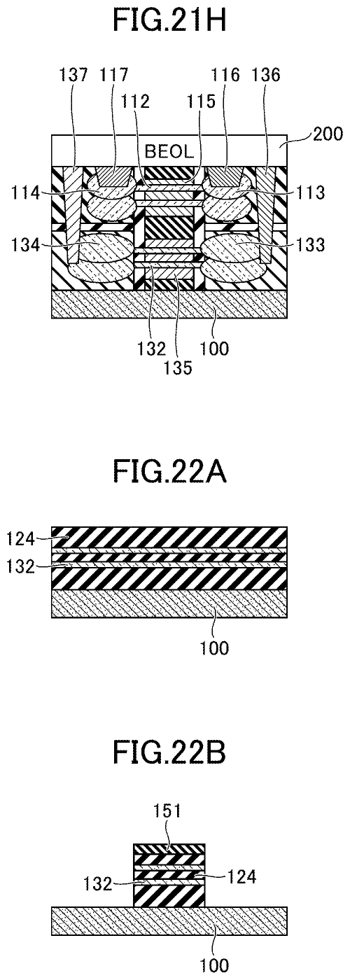

Here, an explanation will be provided in comparison with a method of manufacturing a semiconductor device according to a first reference example. FIG. 21A to FIG. 21H are examples of a cross-sectional view of a semiconductor device for explaining the method of manufacturing the semiconductor device according to the first reference example. In the method of manufacturing the semiconductor device according to the first reference example, a semiconductor device is manufactured by a monolithic CFET.

As illustrated in FIG. 21A, a laminated film in which the N-type channel 112, the P-type channel 132, and an insulating film 123 are laminated is formed on a wafer 100.

Next, as illustrated in FIG. 21B, patterning of the laminated film is performed.

Next, as illustrated in FIG. 21C, an insulating film 151 and the spacer 150 are formed, and the source 133 and the drain 134 of the P-type FET are formed by selective epitaxial growth from the P-type channel 132 on the bottom side.

Next, as illustrated in FIG. 21D, spaces around the source 133 and the drain 134 are filled with the insulating film 170. Then, the source 113 and the drain 114 of the N-type FET are formed by selective epitaxial growth from the N-type channel 112 on the top side.

Next, as illustrated in FIG. 21E, spaces around the source 113 and the drain 114 are filled with the insulating film 171. Then, the insulating films 151 and 123 are etched to form the gate 135 on the P-type channel 132. Then, an insulating film 152 is formed.

Next, as illustrated in FIG. 21F, the gate 115 is formed on the N-type channel 112. Then, an insulating film 153 is formed.

Next, as illustrated in FIG. 21G, the silicide (not illustrated) and the contacts 116, 117, 136, and 137 are formed.

Next, as illustrated in FIG. 21H, wiring (BEOL: Back End of Line) 200 is formed.

### Second Reference Example

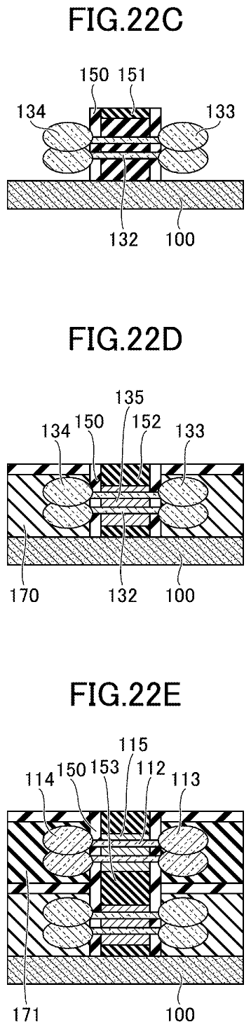

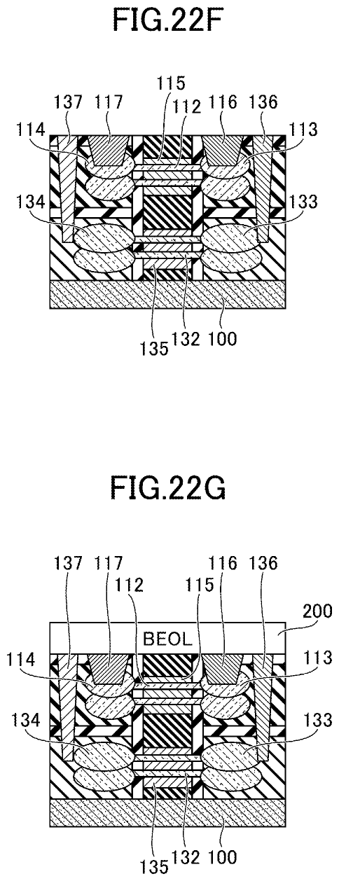

Next, an explanation will be provided in comparison with a method of manufacturing a semiconductor device according to a second reference example. FIG. 22A to FIG. 22G are examples of a cross-sectional view of a semiconductor device for explaining the method of manufacturing the semiconductor device according to the second reference example. In the method of manufacturing the semiconductor device according to the second reference example, a semiconductor device is manufactured by sequential CFET.

As illustrated in FIG. 22A, a laminated film in which the P-type channel 132 and an insulating film 124 are laminated is formed on the wafer 100.

Next, as illustrated in FIG. 22B, the insulating film 151 is formed, and patterning of the laminated film is performed.

Next, as illustrated in FIG. 22C, the spacer 150 is formed, and the source 133 and the drain 134 of the P-type FET are formed by selective epitaxial growth from the P-type channel 132 on the bottom side.

Next, as illustrated in FIG. 22D, spaces around the source 133 and the drain 134 are filled with the insulating film 170. Additionally, the gate 135 is formed. Then, the insulating film 152 is formed.

Next, as illustrated in FIG. 22E, similarly, for the N-type FET, the N-type channel 112, the source 133, the drain 134, the gate 135, and the insulating films 153 and 171 are formed.

Next, as illustrated in FIG. 22F, the silicide (not illustrated) and the contacts 116, 117, 136, and 137 are formed.

Next, as illustrated in FIG. 22G, the wiring (BEOL: Back End of Line) 200 is formed.

Here, in the monolithic CFET, the channel material and the plane orientation need to be the same between the N-type channel and the P-type channel, and there is a problem that the performance of the semiconductor device cannot be improved by using different channel materials and different plane orientations (Problem 1). Additionally, there is a problem in that a region for forming a contact of the transistor on the lower side is needed (Problem 2). Additionally, there is a problem that the process difficulty increases due to a multilayer structure (Problem 3).

Additionally, in the sequential CFET, a thermal budget becomes a problem (Problem 4). Additionally, there is a possibility that the upper and lower devices may be misaligned (Problem 5). Additionally, there is a problem that a region for forming a contact of the transistor on the lower side is needed (Problem 6). Additionally, there is a problem that the cost increases and the fraction defective increases due to the increase in the number of process steps (Problem 7).

With respect to the above, the method of manufacturing the semiconductor device according to the first embodiment has effects of the small misalignment, the easy upper and lower wiring because of no N/P misalignment, and a small increase in the number of processes, which are the advantages of the monolithic CFET. In addition, the method of manufacturing the semiconductor according to the first embodiment has high structural flexibility (optimal channel, source, drain, and contact materials can be used for N-type and P-type, and high expandability to a multilayered structure), which is an advantage of the sequential CFET.

Additionally, according to the method of manufacturing the semiconductor device according to the first embodiment, Problem 1 of the monolithic CFET is solved by bonding the substrates on which the films of the optimal channel materials of the N-type and the P-type are formed. Additionally, Problem 2 can be solved by forming a contact from the back surface side by the proposed method. Additionally, Problem 3 can be solved by repeating the bonding.

Additionally, according to the method of manufacturing the semiconductor device according to the first embodiment, Problem 4 of the sequential CFET can be solved by performing processes in order from a process requiring a high temperature. Additionally, Problem 5 to Problem 7 can be solved by forming the channels and the gates for the N-type and P-type at the same time.

### [Method of Manufacturing Semiconductor Device According to Second Embodiment]

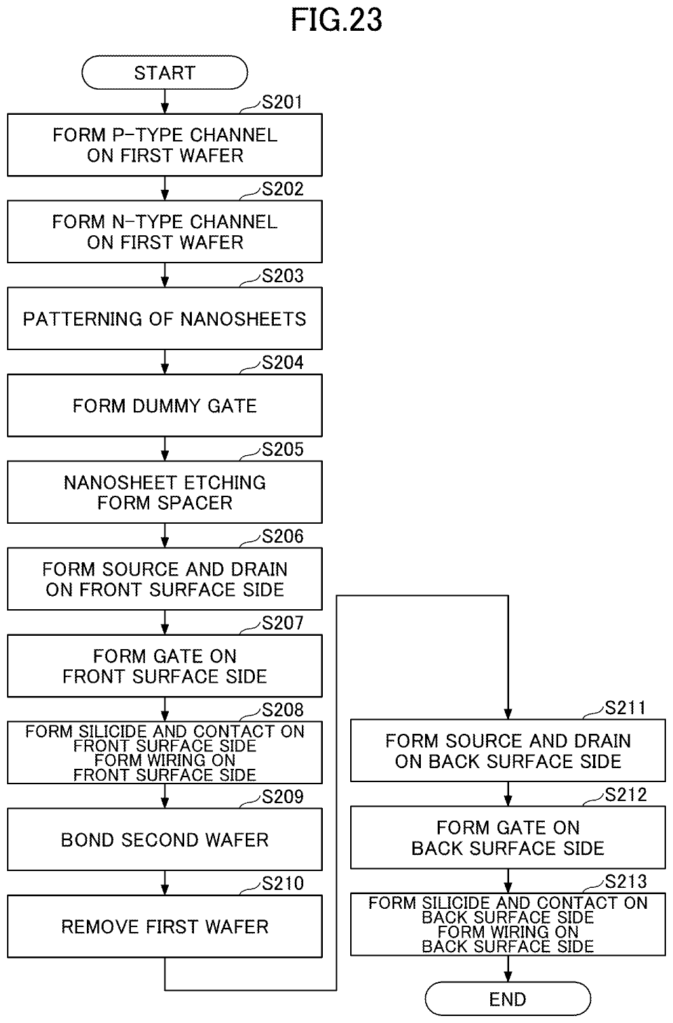

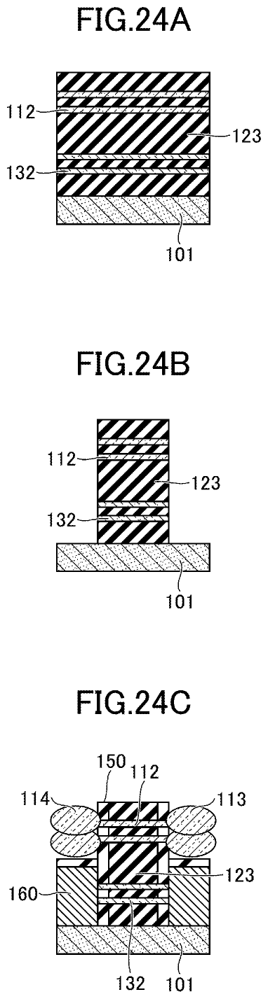

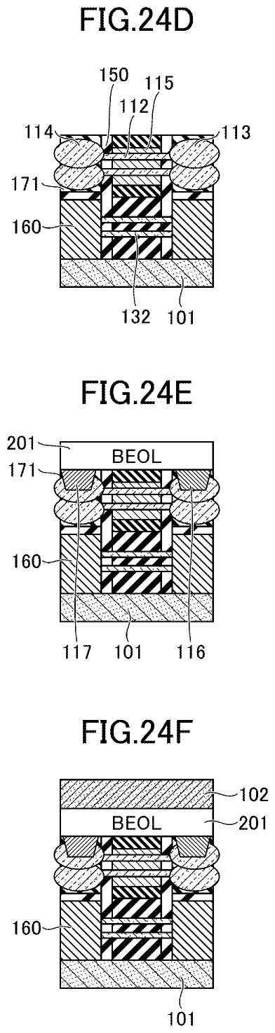

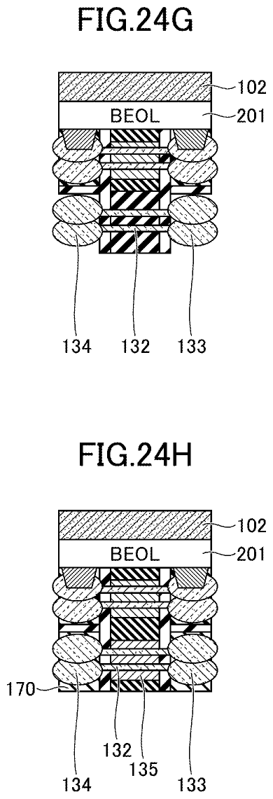

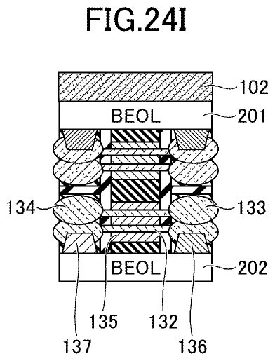

Next, a method of manufacturing a semiconductor device will be described using FIG. 23 and FIG. 24A to FIG. 24I. FIG. 23 is an example of a flowchart for explaining a method of manufacturing a semiconductor device according to a second embodiment. FIG. 24A to FIG. 24I are examples of a cross-sectional view of the semiconductor device for explaining the method of manufacturing the semiconductor device according to the second embodiment.

In step S201, the P-type channel 132 is formed on the first wafer 101.

In step S202, the N-type channel 112 is formed on the first wafer 101. As illustrated in FIG. 24A, the laminated film in which the N-type channel 112, the P-type channel 132, and the insulating film 123 are laminated is formed on the first wafer 101.

In step S203, the first wafer 101 is etched to perform patterning of the nanosheets (see FIG. 24B). Here, the processing of step S203 is substantially the same as the processing of step S105, and thus the duplicated description will be omitted.

In step S204, the dummy gate 140 is formed. Here, the processing of step S204 is substantially the same as the processing of step S106, and thus the duplicated description will be omitted.

In step S205, the nanosheet exposed from the dummy gate 140 is etched to form the spacer 150. Here, the processing of step S205 is substantially the same as the processing of step S107, and thus the duplicated description will be omitted.

In step S206, the source 113 and the drain 114 on the front surface side (the side of the N-type channel 112) are formed (see FIG. 24C). Here, the processing of step S206 is substantially the same as the processing of step S108, and thus the duplicated description will be omitted.

In step S207, the gate 115 on the front surface side (the side of the N-type channel 112) is formed (see FIG. 24D). Here, the processing of step S207 is substantially the same as the processing of step S115, and thus the duplicated description will be omitted.

In step S208, the silicide (not illustrated) and the contacts 116 and 117 are formed for the source 113, the drain 114, and the gate 115 on the front surface side (the side of the N-type channel 112). Additionally, the wiring (BEOL: Back End of Line) 201 is formed on the front surface side (the side of the N-type channel 112) (see FIG. 24E). Here, the processing of step S208 is substantially the same as the processing of step S116, and thus the duplicated description will be omitted.

In step S209, the second wafer 102 is bonded to the first wafer 101 (see FIG. 24F).

In step S210, the first wafer 101 is removed.

In step S211, the source 133 and the drain 134 on the back surface side (the side of the P-type channel 132) are formed (see FIG. 24G). Here, the processing of step S211 is substantially the same as the processing of step S111, and thus the duplicated description will be omitted.

In step S212, the gate 135 on the back surface side (the side of the P-type channel 132) is formed (see FIG. 24H). Here, the processing of step S212 is substantially the same as the processing of step S112, and thus the duplicated description will be omitted.

In step S213, the silicide (not illustrated) and the contacts 136 and 137 are formed for the source 133, the drain 134, and the gate 135 on the back surface side (the side of the P-type channel 132). Additionally, the wiring (BEOL: Back End of Line) 202 is formed on the back surface side (the side of the P-type channel 132) (see FIG. 24I). Here, the processing of step S213 is substantially the same as the processing of step S119, and thus the duplicated description will be omitted.

As described above, according to the method of manufacturing the semiconductor device according to the second embodiment, a semiconductor device having a CFET (complementary FET) structure in which a P-type FET and an N-type FET are vertically stacked can be manufactured.

Additionally, according to the method of manufacturing the semiconductor device according to the second embodiment, the number of times of bonding the wafer and removing the wafer can be reduced.

Here, the method of manufacturing the semiconductor device according to the present embodiment is not limited to the method illustrated in FIG. 2 and FIG. 23.

In the method of manufacturing the semiconductor device according to the first embodiment, as illustrated in step S101 to step S107, the laminated film in which the N-type channel and the P-type channel are laminated is formed together with the wafer being bonded and removed. Additionally, in the method of manufacturing the semiconductor device according to the second embodiment, as illustrated in step S201 to step S205, the films are formed on the wafer to form the laminated film in which the N-type channel and the P-type channel are laminated.

For example, after the laminated film in which the N-type channel and the P-type channel are laminated is formed together with the wafer being bonded and removed as illustrated in step S101 to step S107, the source, the drain, the gate, the contact, the wire, and the like may be formed as illustrated in step S206 to step S213. Additionally, after the films are formed on the wafer to form the laminated film in which the N-type channel and the P-type channel are laminated as illustrated in step S201 to step S205, the source, the drain, the gate, the contact, the wire, and the like may be formed as illustrated in step S108 to step S119.

Additionally, the above description assumes that as illustrated in FIG. 6, the P-type channel 132 is formed on the front surface side and the N-type channel 112 is formed on the back surface side, viewed from the first wafer 101, and as illustrated in FIG. 20, the P-type FET is formed on the lower side (the side closer to the fifth wafer 105) and the N-type FET is formed on the upper side (the side farther from the fifth wafer 105), viewed from the fifth wafer 105, but is not limited thereto. The semiconductor device may be formed such that the vertical arrangement of the P-type FET and the N-type FET is reversed. For example, the P-type channel may be formed on the first wafer 101 in step S101, and the N-type channel may be formed on the second wafer 102 in step S102. With this, a semiconductor device in which the vertical arrangement of the P-type FET and the N-type FET is reversed in comparison with the semiconductor device illustrated in FIG. 20 can be formed.

Additionally, the above description assumes that as illustrated in FIG. 24A, the N-type channel 112 is formed on the front surface side and the P-type channel 132 is formed on the back surface side, viewed from the first wafer 101, and as illustrated in FIG. 24I, the N-type FET is formed on the lower side (the side closer to the second wafer 102) and the P-type FET is formed on the upper side (the side farther from the second wafer 102), viewed from the second wafer 102, but is not limited thereto. The semiconductor device may be formed such that the vertical arrangement of the P-type FET and the N-type FET is reversed. For example, the N-type channel may be formed on the first wafer 101 in step S201, and the P-type channel may be formed on the first wafer 101 in step S202. With this, a semiconductor device in which the vertical arrangement of the P-channel FET and the N-channel FET is reversed in comparison with the structure illustrated in FIG. 24I can be formed.

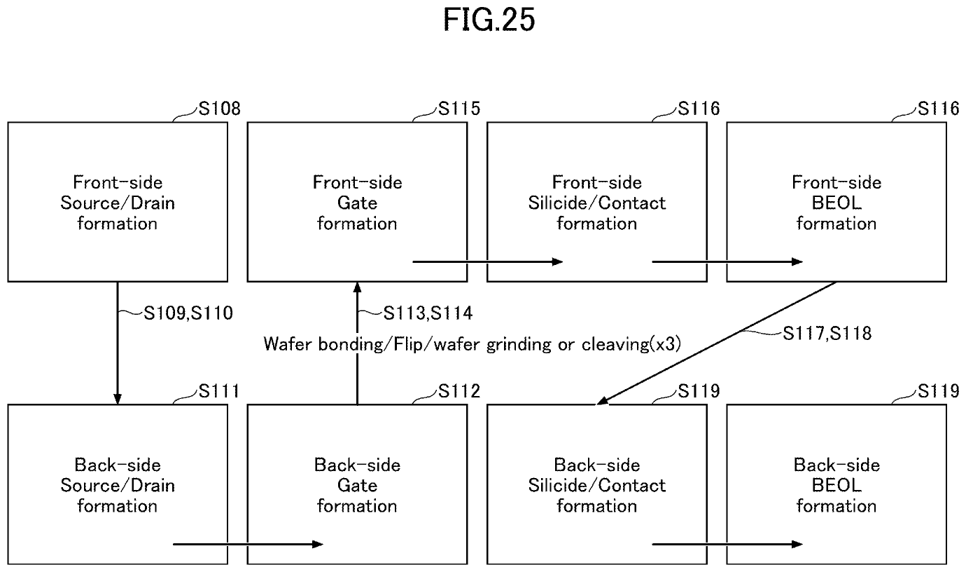

FIG. 25 is an example of a block diagram for explaining the method of manufacturing the semiconductor device according to the first embodiment.

In the method of manufacturing the semiconductor device according to the first embodiment illustrated in FIG. 25, the process is performed in the order of forming the source and drain on the front surface side (S108), bonding and removing the wafer (S109 and S110), forming the source and drain on the back surface side (S111), forming the gate on the back surface side (S112), bonding and removing the wafer (S113 and S114), forming the gate on the front surface side (S115), forming the silicide and contact on the front surface side (S116), forming the wire (BEOL on the front surface side (S116), bonding and removing the wafer (S117 and S118), forming the silicide and contact on the back surface side (S119), and forming the wire (BEOL) on the back surface side (S119). Here, in the method of manufacturing the semiconductor device according to FIG. 25, the bonding and removing of the wafer are performed three times. In the flowchart for explaining the method of manufacturing the semiconductor device according to the first embodiment illustrated in FIG. 2, the laminated film is formed on the wafer by using the bonding and the removing the first wafer 101 and the second wafer 102 (see S103 and S104), and thus the bonding and removing of the wafer are performed four times in total.

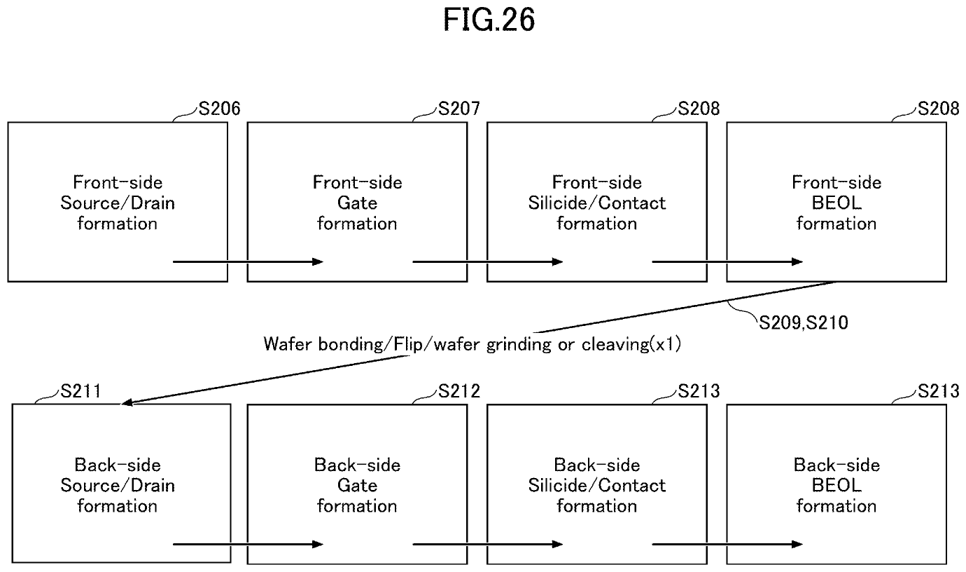

FIG. 26 is an example of a block diagram for explaining the method of manufacturing the semiconductor device according to the second embodiment.

In the method of manufacturing the semiconductor device according to the second embodiment illustrated in FIG. 26, the process is performed in the order of forming the source and drain on the front surface side (S206), forming the gate on the front surface side (S207), forming the silicide and contact on the front surface side (S208), forming the wire (BEOL) on the front surface side (S208), bonding and removing the wafer (S209 and S210), forming the source and drain on the back surface side (S211), forming the gate on the back surface side (S212), forming the silicide and contact on the back surface side (S213), and forming the wire (BEOL) on the back surface side (S213). Here, in the method of manufacturing the semiconductor device according to FIG. 26, the bonding and removing of the wafer are performed once. In the flowchart for explaining the method of manufacturing the semiconductor device according to the second embodiment illustrated in FIG. 23, the films are formed on the wafer to form the laminated film (see S201 to S205), and thus the number of times of bonding and removing of the wafer remains one in total.

The method of manufacturing the semiconductor device according to the present embodiment may be configured to perform the process in the order of, for example, forming the source and drain on the front surface side, forming the gate on the front surface side, bonding and removing the wafer, forming the source and drain on the back surface side, forming the gate on the back surface side, forming the silicide and contact on the back surface side, forming the wiring on the back surface side, bonding and removing the wafer, forming the silicide and contact on the front surface side, and forming the wiring on the front surface side. Here, in this configuration, the bonding and removing of the wafer are performed twice.

Additionally, the method of manufacturing the semiconductor device according to the present embodiment may be configured to perform the process in the order of, for example, forming the source and drain on the front surface, bonding and removing the wafer, forming the source and drain on the back surface, forming the gate on the back surface, forming the silicide and contact on the back surface, forming the wiring on the back surface, bonding and removing the wafer, forming the gate on the front surface, forming the silicide and contact on the front surface, and forming the wiring on the front surface. Here, in this configuration, the bonding and removing of the wafer are performed twice.

Although the embodiments of the method of manufacturing the semiconductor device and the like have been described above, the present disclosure is not limited to the above-described embodiments and the like, and various modifications and improvements can be made within the scope of the spirit of the present disclosure described in the claims.

This application claims priority to Japanese Patent Application No. 2021-172576 filed on Oct. 21, 2021, the entire contents of which are incorporated herein by reference.

### DESCRIPTION OF REFERENCE SYMBOLS

100 to 105 wafer
111 dummy film
112 N-type channel
113 source
114 drain
115 gate
116, 117 contact
131 dummy film
132 P-type channel
133 source
134 drain
135 gate
136, 137 contact
200 to 202: wiring
900 semiconductor device

1. A method of manufacturing a semiconductor device, comprising:
forming a laminated film by laminating an N-type channel and a P-type channel on a substrate;
performing patterning on the laminated film;
forming a source and a drain on a front surface side;
bonding a new substrate on the front surface side and removing the substrate on a back surface side;
forming a source and a drain on the back surface side; and
forming a gate on the back surface side.

2. The method of manufacturing the semiconductor device as claimed in claim 1, comprising:
bonding a new substrate on the back surface side and removing the substrate on the front surface side; and
forming a gate on the front surface side.

3. The method of manufacturing the semiconductor device as claimed in claim 2, comprising:
bonding a new substrate on the front surface side and removing the substrate on the back surface side;
forming a contact on the back surface side; and
forming wiring on the back surface side.

4. A method of manufacturing a semiconductor device, comprising:
forming a laminated film by laminating an N-type channel and a P-type channel on a substrate;
performing patterning on the laminated film;
forming a source and a drain on a front surface side;
forming a gate on the front surface side;
bonding a new substrate on the front surface side and removing the substrate on a back surface side;
forming a source and a drain on the back surface side; and
forming a gate on the back surface side.

5. The method of manufacturing the semiconductor device as claimed in claim 4, comprising:
forming a contact on the front surface side and forming wiring on the front surface side after the step of forming the gate on the front surface side yet before the step of bonding the new substrate on the front surface side and removing the substrate on the back surface side; and
forming a contact on the back surface side and forming wiring on the back surface side after the step of forming the gate on the back surface side.

6. The method of manufacturing the semiconductor device as claimed in claim 1, wherein the forming of the laminated film by laminating the N-type channel and the P-type channel on the substrate includes bonding a substrate on which the N-type channel is formed and a substrate on which the P-type channel is formed to each other, and removing one substrate.

7. A semiconductor device comprising a first transistor formed on a back surface side and a second transistor formed on a front surface side are laminated,
wherein first wiring and a contact formed on the back surface side is connected to the first transistor, and
wherein second wiring and a contact formed on the front surface side is connected to the second transistor.
